(19) United States
(12) Patent Application Publication
(10) Pub. No.: US 2014/0182657 A1
(43) Pub. Date: Jul. 3, 2014

(54) CONCENTRATING SOLAR CELL MODULE AND METHOD FOR PRODUCING CONCENTRATING SOLAR CELL MODULE

(71) Applicant: SHIN-ETSU CHEMICAL CO., LTD., Tokyo (JP)

(72) Inventors: Wataru GOTO, Annaka (JP); Toshio SHIOBARA, Annaka (JP)

(73) Assignee: SHIN-ETSU CHEMICAL CO., LTD., Tokyo (JP)

(21) Appl. No.: 14/088,741

(22) Filed: Nov. 25, 2013

(30) Foreign Application Priority Data
Dec. 27, 2012 (JP) 2012-286075

(51) Int. Cl. H01L 31/052

(52) U.S. Cl. CPC H01L 31/0525
USPC 136/246; 438/65

(57) ABSTRACT

The present invention provides a concentrating solar cell module comprising: a base portion having a plurality of mounting regions for mounting solar cells and a plurality of lead electrodes for electrically connecting the solar cells with external electrodes; a support molded with a thermosetting resin such that each of the mounting regions of the base portion is surrounded; the solar cells mounted on the mounting regions; and a condensing lens molded above the mounting regions so as to encapsulate the solar cells, wherein a surface of the mounting regions of the base portion is plated and the condensing lens is molded with a transparent thermosetting silicone resin. The concentrating solar cell module has high heat dissipation properties and a high photoelectric conversion efficiency.

### BACKGROUND OF THE INVENTION

1. Field of the Invention

The present invention relates to a concentrating solar cell module having a structure for concentrating and irradiating a solar cell with high-energy sunlight and a method for producing the same.

2. Description of the Related Art

As a system of a solar module, a flat plate system in which solar cells are arranged over a sunlight-receiving surface is often used. Unfortunately, solar cells, which are arranged according to according to the area of the receiving surface, have a high cost, and hence the solar module also has a high cost. From such a background, a concentrating solar cell module in which sunlight is concentrated on a small-diameter solar cell by a condensing lens has been developed. The concentrating solar cell module allows the number of required solar cells to be reduced by concentrating light several hundred times in comparison with the flat plate system.

The concentrating solar cell module that concentrates light several hundred times needs a sunlight-receiving surface having a mechanism of tracking the movement of the sunlight, resulting in an increase in cost and an increase in size of the solar module to install this mechanism.

In order to solve the problem, a concentrating solar cell module having a resin structure for concentration (e.g., fresnel lens and convex lens), formed above solar cells, has been proposed to reduce the size and cost of the solar module (see Patent Document 1). In Patent Document 1, concentration structures each composed of materials having different refractive indexes are formed in a recess of a support.

### CITATION LIST

### Patent Literature

[Patent Document 1] Japanese Patent Application Publication No. H9-83006

### SUMMARY OF THE INVENTION

Unfortunately, the concentrating solar cell module in Patent Document 1 has problems in that light enters the support to reduce the photoelectric conversion efficiency and selection of materials for the support and the concentration structure is complicated.

Further, in the concentrating solar cell module, the temperature of the solar cells reaches 80° C. or higher during irradiation with light. This results in a problem of a decrease in the output of the concentrating solar cell module. Therefore, in the concentrating solar cell module, it is an important to improve heat dissipation properties and increase photoelectric conversion efficiency.

The present invention has been made in view of the above situations, and an object of the present invention is to provide a concentrating solar cell module having high heat dissipation properties and a high photoelectric conversion efficiency, and a method for producing the concentrating solar cell module.

In order to achieve the object, the present invention provides a concentrating solar cell module comprising: a base portion having a plurality of mounting regions for mounting solar cells and a plurality of lead electrodes for electrically connecting the solar cells with external electrodes; a support molded with a thermosetting resin so as to surround each of the mounting regions of the base portion; the solar cells mounted on the mounting regions; and a condensing lens molded above the mounting regions so as to encapsulate the solar cells, wherein a surface of each of the mounting regions of the base portion is plated and the condensing lens is molded with a transparent thermosetting silicone resin.

Such a concentrating solar cell module is excellent in photoelectric conversion efficiency, heat resistance, and durability due to the condensing lens molded with a transparent thermosetting silicone resin. Further, the heat dissipation properties are improved by the plating on the surface of the mounting regions. Therefore, degradation of the photoelectric conversion efficiency due to high temperature can be suppressed.

The support is preferably molded with a thermosetting resin containing a silicone resin having a reflectance of 90% or more with respect to a light with a wavelength ranging from 350 nm to 900 nm.

Such a concentrating solar cell module surely can improve its photoelectric conversion efficiency, heat resistance, and durability.

An inner wall surface of the support is preferably coated with metal by vapor deposition or plating.

Such a concentrating solar cell module can further improve its photoelectric conversion efficiency, and reduce its cost.

The mounted solar cells are preferably connected to the respective plated mounting regions through metal or a conductive thermosetting silicone resin.

Such a concentrating solar cell module is excellent in heat dissipation properties.

The support may be formed from at least one material selected from a thermosetting silicone resin, an organic modified silicone resin, and a mixed resin of an epoxy resin and a silicone resin.

Such a concentrating solar cell module is excellent in light stability and heat resistance.

The support may contain at least one selected from the group consisting of a filler, a dispersing agent, a pigment, a fluorescent substance, a reflective substance, a light-shielding substance, and a fibrous inorganic material.

Such a concentrating solar cell module has high durability and high photoelectric conversion efficiency due to the support having high reflectivity and high strength.

The present invention also provides a method for producing a concentrating solar module comprising the steps of: preparing a base portion having a plurality of mounting regions for mounting solar cells and a plurality of lead electrodes for electrically connecting the solar cells with external electrodes; molding a support with a thermosetting resin so as to surround each of the mounting regions of the base portion; mounting the solar cells on the mounting regions; plating a surface of the mounting regions of the prepared base portion after the preparing step and before the mounting step; and molding a condensing lens above the mounting regions so as to encapsulate the solar cells, wherein the condensing lens is molded with a transparent thermosetting silicone resin in the step of molding the condensing lens.

Such a method enables production of a concentrating solar cell module excellent in photoelectric conversion efficiency, heat resistance, and durability by molding the condensing lens with a transparent thermosetting silicone resin. Also, the method including plating the surface of the mounting regions enables production of a concentrating solar cell module having improved heat dissipation properties and capable of suppressing degradation of photoelectric conversion efficiency due to high temperature.

In the method, an inner wall surface of the support is preferably coated with metal by vapor deposition or plating after the step of molding the support and before the step of molding the condensing lens.

Thus, a concentrating solar cell module having a further improved photoelectric conversion efficiency can be produced at low cost.

The mounted solar cells are preferably connected to the respective plated mounting regions through metal or a conductive thermosetting silicone resin in the mounting step.

In such a manner, a concentrating solar cell module having more excellent heat dissipation properties can be produced.

After the step of molding the condensing lens, a part of the base portion may be cut to form an electric circuit.

In such a manner, an electrical connection state of each solar cell can be checked in the course of producing the concentrating solar cell module, and thereby a failure solar cell can be sorted out. Accordingly, the inspection in the steps can be simplified, and the cost can be reduced.

The condensing lens may be molded by compression molding, transfer molding, injection molding, or cast molding in the step of molding the condensing lens.

In such a manner, the production can be simplified, the production efficiency can be improved, and the cost can be reduced.

In the method, the concentrating solar module may be cut by dicing into individual concentrating solar modules after the step of molding the condensing lens.

Such a method enables mass production of the concentrating solar cell modules, thereby reducing the cost.

In the production of a concentrating solar cell module of the present invention, the surface of each of the mounting regions of the base portion is plated, and the condensing lens is molded with a transparent thermosetting silicone resin. The produced concentrating solar cell module of the present invention is therefore excellent in the photoelectric conversion efficiency and the heat resistance, has improved heat dissipation properties, and can suppress degradation of photoelectric conversion efficiency due to high temperature.

### BRIEF DESCRIPTION OF THE DRAWINGS

FIG. 1 is a schematic view of an example of a concentrating solar cell module of the present invention;

FIG. 2 is a schematic view of an example of an individual piece into which a concentrating solar cell module of the present invention has been cut;

FIG. 3 is a schematic view of another example of an individual piece into which a concentrating solar cell module of the present invention has been cut;

FIG. 4 is a flow chart of an example of a method for producing a concentrating solar cell module of the present invention; and

FIG. 5 is an explanatory view of a method for forming an electric circuit on a concentrating solar cell module.

### DETAILED DESCRIPTION OF THE PREFERRED EMBODIMENTS

Hereinafter, embodiments in the present invention will be described, but the present invention is not limited to these embodiments.

As described above, it is important not only to produce a concentrating solar cell module having a high photoelectric conversion efficiency but also to maintain the high photoelectric conversion efficiency by improving the heat dissipation properties.

The present inventor has extensively investigated to solve this problem. As a result, the inventor has found that the problem can be solved by plating each surface of mounting regions for mounting solar cells, thereby brought the present invention to completion.

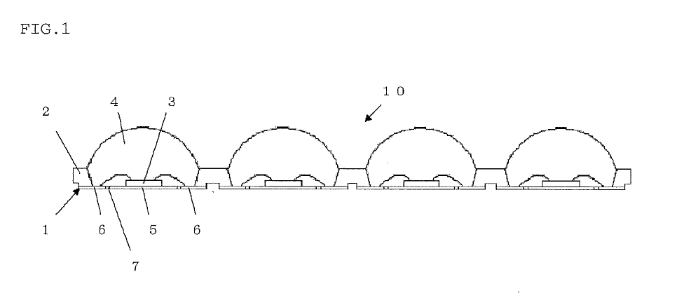

FIG. 1 is a schematic view of an example of a concentrating solar cell module of the present invention. As shown in FIG. 1, a concentrating solar cell module 10 includes a base portion 1, a support 2, solar cells 3, and condensing lenses 4.

The base portion 1 has mounting regions 5 for mounting the solar cells 3 and lead electrodes 6 for electrically connecting the solar cells 3 with external electrodes. The mounting regions 5 and lead electrodes 6 are each provided so as to correspond to the solar cells 3 to be mounted.

The surface of each of the mounting regions 5 of the base portion 1 is plated. In addition, the surface of each of the lead electrodes 6 may be plated. Metal used for the plating is not particularly limited, and aluminum, chromium, zinc, gold, silver, platinum, nickel, palladium, or an alloy thereof (e.g., Ni—Ag and Ni—Pd—Au) can be used.

The base portion 1 may be a metal lead frame obtained by etching a metal plate to form lead electrodes, for example. In this case, as shown in FIG. 1, a resin may be embedded in portions 7 etched for forming lead electrodes to strengthen the base portion 1. Alternatively, the base portion 1 may be a resin substrate, a ceramic substrate, or a glass cloth substrate having plated mounting regions 5 and lead electrodes 6 formed by plating the surface of the substrate.

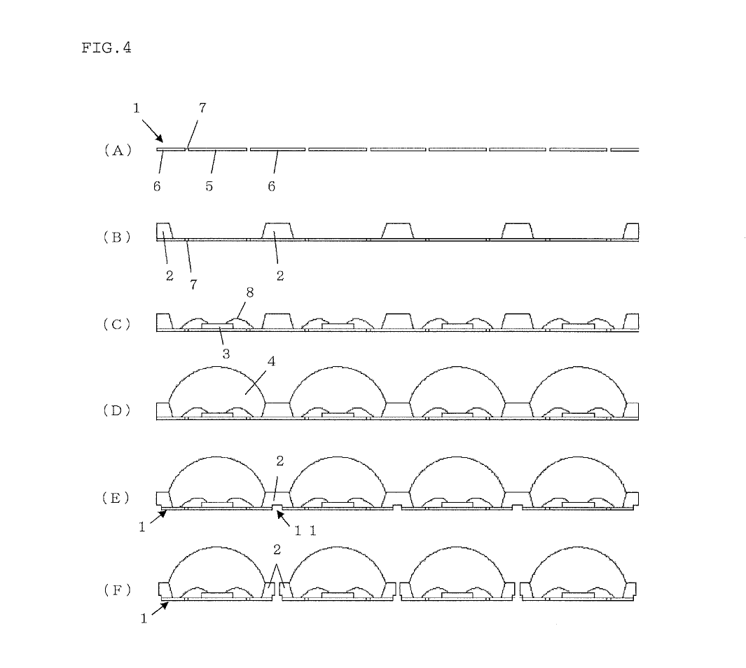

The support 2 is molded with a thermosetting resin so as to surround each of the mounting regions 5 of the base portion 1. The base portion 1 on which the support 2 is in the form of an assembled solar cell-housing package in which the support 2 having a recess having the mounting region 5 at the bottom is molded (see FIG. 4 at (B)). In an example of the concentrating solar cell module 10 shown in FIG. 1, the support 2 is molded in a tapered shape in which the recess laterally extends gradually toward the top.

The solar cells 3 are mounted on the respective mounting regions 5 plated in the above manner with a light-receiving portion faced upward. The heat dissipation properties of the concentrating solar cell module can therefore be significantly improved. The solar cells 3 are not particularly limited, and may be composed of a semiconductor of single crystal silicon, polycrystalline silicon, or III-V group compound, such as gallium arsenide, aluminum-gallium arsenide, and indium phosphorus gallium-indium phosphorus, for example.

The mounted solar cells 3 is preferably connected to the respective plated mounting regions 5 through metal or a conductive thermosetting silicone resin.

Connecting the solar cells 3 with the mounting regions 5 makes handling easy during molding the condensing lens 4 in the production of the concentrating solar cell module, and prevents the heat dissipation properties from being reduced.

The condensing lenses 4 are molded with a transparent thermosetting silicone resin above the respective mounting regions 5 so as to encapsulate the respective solar cells 3. For example, the condensing lens 4 may be in the form of a convex lens or a fresnel lens. Such a concentrating solar cell module is excellent in the photoelectric conversion efficiency.

It is effective to prevent light from passing through or being absorbed into the support 2 to ensure a high photoelectric conversion efficiency. Accordingly, the support 2 preferably have a high reflectance. In particular, the support is preferably molded with a thermosetting resin containing a silicone resin having a reflectance of 90% or more with respect to a light with a wavelength ranging from 350 nm to 900 nm. Such a concentrating solar cell module can ensure a high photoelectric conversion efficiency by improving efficiency of concentrating light and have a high heat resistance and a high durability.

In order to improve the reflectance of the support 2, the inner wall surface of the support 2 may be coated with metal by vapor deposition or plating. The reflectance of the support 2 can be increased to 99% by plating the inner wall surface of the support 2 with nickel, for example. Accordingly, the complicated conventional selection of a material can be eliminated, and a concentrating structure, that is, a structure for irradiating a solar cell with sunlight, can be configured only by the support 2, the base portion 1, and the condensing lens 4.

Metal used for plating the inner wall surface of the support 2 is not limited to nickel, and may be gold, which has a high reflectance, for example. In addition, a metal such as aluminum, chromium, zinc, silver, and platinum, an oxide such as SiO₂ and TiO₂, or a fluoride such as ZrO₂ and MgF₂ may be used. Further, not only plating but also vapor deposition may be performed. Adding a high-reflective substance such as titanium oxide into the support 2 enhances the reflectance of the support 2.

If necessary, the surface of the condensing lens 4 and/or the solar cell 3 may be coated with a protection film of a synthetic resin or a film for adjusting refractive index. The film prevents the surface from damaging due to an external factor and adjusts the refractive index to further improve the sunlight concentrating efficiency.

For the support 2, for example, a thermosetting resin such as an epoxy resin, a modified epoxy resin, a silicone resin, a modified silicone resin, an acrylate resin, a urethane resin, and a mixed resin of an epoxy resin and a silicone resin may be used.

Examples of the thermosetting resin include 1) a thermosetting silicone resin composition, 2) a thermosetting epoxy resin composition including a triazine derivative epoxy resin, an acid anhydride, a curing accelerator, and an inorganic filling agent, and 3) a hybrid resin (mixed resin) composition of a thermosetting silicone resin and an epoxy resin. However, the thermosetting resin is not limited to these resins, and may be determined according to the final application for a concentrating solar cell module.

Notable examples of the thermosetting silicone resin composition described above as 1) include a condensed thermosetting silicone resin composition represented by the following average composition formula (1):

R¹ₐSi(OR²)_{b}(OH)_{c}O_{(4-a-b-c)/2} (1)

wherein R¹ represents the same or different organic group having 1 to 20 carbon atoms, R² represents the same or different organic group having 1 to 4 carbon atoms, and “a”, “b”, and “c” represent numbers satisfying 0.8≦a≦1.5, 0≦b≦0.3, 0.001≦c≦0.5, and 0.801≦a+b+c<2.

From the viewpoint of heat resistance and light stability, the triazine derivative epoxy resin in the thermosetting epoxy resin described above as 2) is preferably a 1,3,5-triazine nucleus derivative epoxy resin. The thermosetting epoxy resin composition is not limited to one including a triazine derivative and an acid anhydride as a curing agent, and may be conventionally known epoxy resin, amine, and phenol curing agent.

Examples of the hybrid resin of a silicone resin and an epoxy resin described above as 3) include a copolymer of an epoxy resin and a silicone resin.

An inorganic filler may be mixed in the silicone resin composition or the epoxy resin composition. As the inorganic filler to be mixed, a material that is generally mixed in a silicone resin composition or an epoxy resin composition can be used. Examples thereof include silica such as molten silica and crystalline silica, alumina, silicon nitride, aluminum nitride, boron nitride, glass fiber, a fibrous filler such as wollastonite, and antimony trioxide. The average particle diameter and the shape thereof are not particularly limited.

Titanium dioxide can be mixed in the resin composition used in the present invention. Titanium dioxide can be mixed as a white colorant to enhance the whiteness degree and improve the reflective efficiency of light. The unit lattice of the titanium dioxide may be a rutile type or an anatase type. Further, the average particle diameter and the shape thereof are not limited. In order to enhance the compatibility with a resin or an inorganic filler and the dispersibility, titanium dioxide can be surface-treated in advance with a hydrous oxide of Al or Si.

The filling amount of the titanium dioxide is preferably 2 to 30% by mass, and particularly preferably 5 to 10% by mass, relative to the whole amount of the composition. When the amount is 2% by mass or more, a sufficient whiteness degree can be obtained, and when the amount is 30% by mass or less, poor molding such as not filling and void is not seen.

The support 2 may contain at least one selected from the group consisting of a filler, a dispersing agent, a pigment, a fluorescent substance, a reflective substance, a light-shielding substance, and a fibrous inorganic material.

Such a concentrating solar cell module has high durability and high photoelectric conversion efficiency due to the support having high reflectivity and high strength.

Next, a method for producing a concentrating solar cell module of the present invention will be described.

As shown in FIG. 4, a base portion 1 having a plurality of mounting regions 5 for mounting a plurality of solar cells and a plurality of lead electrodes 6 for electrically connecting the solar cells with external electrodes is prepared. The surface of each of the mounting regions 5 of the prepared base portion 1 is plated (FIG. 4 at (A): preparing step and plating step). At this time, when the metal lead frame as described above is prepared as the base portion 1, a metal plate is etched to form lead electrodes, the surface of each of the mounting regions 5 is plated. The surface of each of the lead electrodes 6 is also plated, if necessary. Thus, a concentrating solar cell module having high heat dissipation properties can be produced at low cost.

Alternatively, a resin substrate, a ceramic substrate, or a glass cloth substrate of which the surface is plated to form plated mounting regions 5 and lead electrodes 6 may be prepared as the base portion 1.

Subsequently, a support is molded with a thermosetting resin so as to surround each of the mounting regions 5 of the base portion 1 (FIG. 4 at (B): support molding step). According to this step, an assembled solar cell-housing package in which in which the support 2 having a recess having the mounting region 5 at the bottom is molded can be produced. Thus, the support 2 can be molded in a tapered shape in which the recess laterally extends gradually toward the top.

The support 2 can be molded by transfer molding or injection molding. At this time, it is preferable that the support 2 be molded by transfer molding while each of the lead electrodes 6 is cramped with upper and lower molds to prevent resin burr from occurring on the lead electrodes 6 electrically connecting to external electrodes. The thermosetting resin used in the molding of the support 2 may be the same as described in the concentrating solar cell module. When the metal lead frame is used as the base portion 1, the thermosetting resin may be embedded in portions 7 etched for forming lead electrodes while the support 2 is molded, as shown in FIG. 4 at (B), to strengthen the concentrating solar cell module.

In order to configure a highly reflective structure of the support 2, a highly reflective substance such as titanium oxide can be mixed in the thermosetting resin. Alternatively, after the support 2 is molded, the inner wall surface of the support may be coated with metal by vapor deposition or plating. In this case, the lead electrodes 6 may be masked, for example, with a polyimide tape to prevent the high reflective substance from adhering to the lead electrodes 6 of the base portion 1. This step may be performed after the support molding step and before the condensing lens molding step. Metal used for plating in this step may be the same as described in the concentrating solar cell module.

Next, the solar cells 3 are mounted on the respective plated mounting regions 5 (FIG. 4 at (C): mounting step). The solar cells 3 are mounted with a light-receiving portion faced upward. The solar cells 3 is preferably connected to the mounting regions 5 through metal or a conductive thermosetting silicone resin. In this case, in consideration of heat dissipation properties and conductivity, Au—Sn is preferably used as metal and a conductive thermosetting silicone resin is preferably used as a conductive resin paste.

The solar cells 3 can be electrically connected to the lead electrodes 6 through wires 8 such as a gold wire or a copper wire by wire bonding. Alternatively, the solar cells 3 can be electrically connected to the lead electrodes 6 through a sub-mount substrate.

At this time, when the solar cells 3 cannot be electrically connected to the lead electrodes 6 by wire bonding due to the size of the support 2, for example, the support molding step may be performed after the mounting step.

Subsequently, condensing lenses 4 are molded above the respective mounting regions 5 so as to encapsulate the respective solar cells 3 (FIG. 4 at (D): condensing lens molding step). In this step, the recess of the support 2 is filled with a transparent thermosetting silicone resin with fluidity to mold a condensing lens 4. Thus, a concentrating solar cell module having excellent heat dissipation properties, heat resistance, and durability can be produced.

The condensing lenses 4 may be molded by compression molding, transfer molding, or injection molding. Thus, the production can be simplified, the production efficiency can be improved, and the cost can be reduced. Alternatively, the condensing lenses 4 can be molded by dripping a resin.

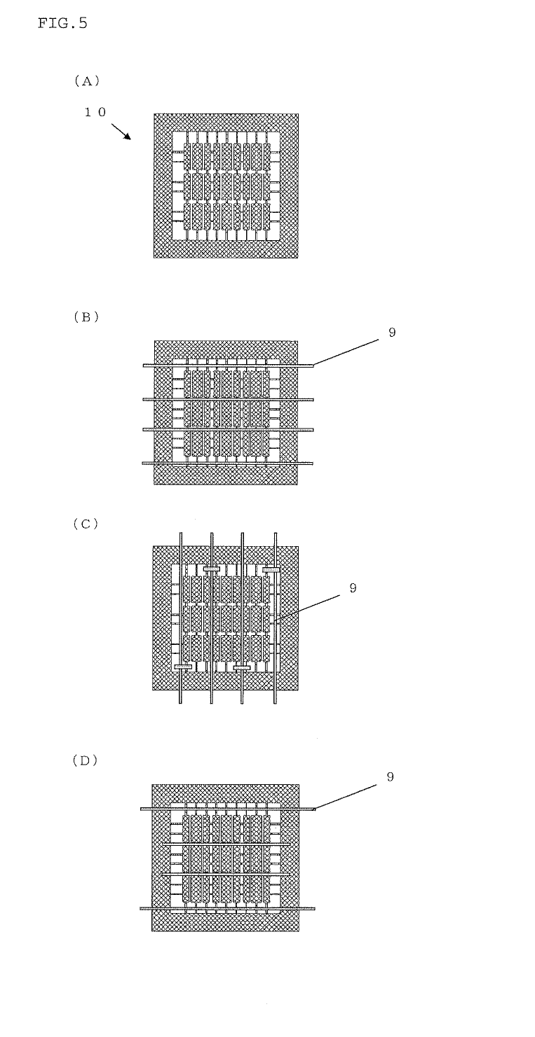

After the condensing lens molding step, a portion of the base portion 1 is cut to form an electric circuit, if necessary (FIG. 4 at (E)). FIG. 5 illustrates an example of a method for forming an electric circuit. At (A) in FIG. 5, the concentrating solar cell module 10 after molding of the condensing lens 4 is illustrated from its back side. At (B) to (D) in FIG. 5, the base portion 1 is cut with a dicing blade. As shown in FIG. 5 at (B) to (D), a portion of the base portion 1 is cut from the back side of the concentrating solar cell module with a dicing blade 9 in this step. At this time, only a portion of the base portion or the base portion 1 and only a portion of the support 2 is cut but the support 2 is not completely cut (half dicing), as indicated by the numeral 11 in FIG. 4 at (E). In this way, it is possible to form three kinds of electric circuits including a serial circuit (FIG. 5 at (B)), a parallel circuit (FIG. 5 at (C)), and a series-parallel circuit (FIG. 5 at (D)).

Forming the electric circuit in this way enables not only an inspection for checking electric short circuit and an open state during the production but also elimination of a printed circuit board for electrically connecting with external electrodes, and the concentrating solar cell module can thus be produced at low cost.

After the condensing lens molding step, the concentrating solar module may be cut by dicing into individual concentrating solar modules (FIG. 4 at (F)). In this step, as shown in FIG. 4 at (F), both the base portion 1 and the support 2 are completely cut by dicing (full dicing). Thus, individual concentrating solar cell modules can be mass-produced, and the productivity is significantly improved.

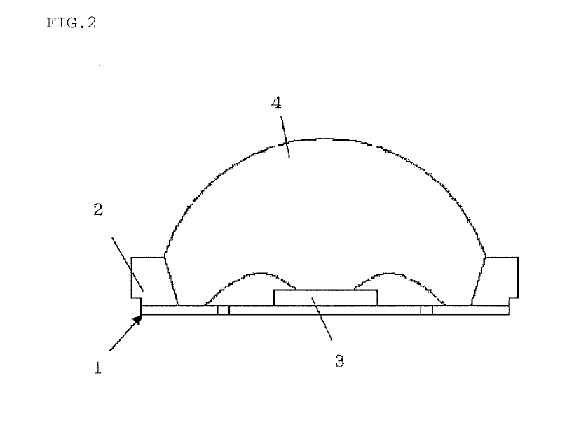

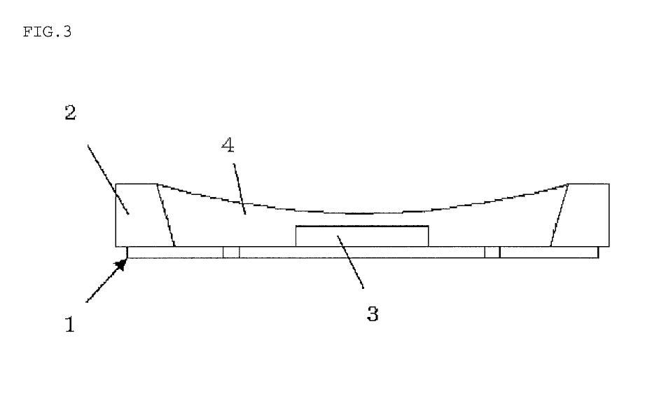

FIGS. 2 and 3 show an example of an individual concentrating solar cell module. In the individual concentrating solar cell module shown in FIG. 2, the condensing lens 4 is molded with a mold such that the condensing lens 4 has an upward convex shape. In the individual concentrating solar cell module shown in FIG. 3, the condensing lens 4 is molded by dripping a resin through the surface tension with a dispenser such that the condensing lens 4 has a downward convex shape.

According to the production method including a step of cutting a concentrating solar cell module by dicing, a location of a solar battery is not restricted, and a space for a solar battery can be saved.

### EXAMPLES

Hereinafter, the present invention will be more specifically described with reference to Examples and Comparative Examples, but the present invention is not limited to these Examples.

### Example 1

A plurality of mounting regions and lead electrodes were formed by using a Cu-based substrate (Tamac194 manufactured by Mitsubishi Shindoh Co., Ltd.) with a thickness of 0.25 mm through an etching process, and the surfaces of the mounting regions and the lead electrodes were plated with Ni/Pd/Au to produce a metal lead frame as a base portion, as shown in FIG. 4 at (A). The surface of the base portion was subjected to a plasma treatment under conditions of 50 W and 60 seconds. Then, a support was molded with a thermosetting silicone composition by a transfer molding apparatus. Thus, an assembly solar cell housing package was produced.

The mounting regions were then masked with a polyimide tape, and the inner wall surface of the support was plated with Ni. After the masking was removed, an Au/Sn ribbon (manufactured by Sumitomo Metal Mining Co., Ltd., trade name: Alloy Preform, Au: 80%, Sn: 20%) was cut to be disposed on the mounting regions. Solar cells (manufactured by Cyrium Technologies, three-junction compound type, 2.5 mm×2.5 mm) were then mounted on the mounting regions and subjected to eutectic bonding at 280° C. The mounted solar cells were electrically connected to the respective lead electrodes through gold wires of 30 μm.

Then, condensing lenses were molded with a thermosetting silicone resin (available from Shin-Etsu Chemical Co., Ltd., trade name: KJP-9022) by a compression molding apparatus manufactured by TOWA Corporation.

As shown in FIG. 5 at (B), a portion of the base portion was then cut (half dicing) by a dicing blade having a thickness of 0.4 mm to form an electronic circuit in which three series electronic circuits with three solar cells are arranged in three rows. A concentrating solar cell module having the electronic circuit was thus produced. On the outer peripheral portion of the concentrating solar cell module, an energization probe was disposed, and connected with the lead electrodes to perform an energization test so that a connection state between the solar cell and the gold wires was checked.

Subsequently, the concentrating solar cell module was cut (full dicing) into nine concentrating solar cell modules, as shown in FIG. 2, by a dicing blade having a thickness of 0.2 mm. Since the cut concentrating solar cell modules had been already subjected to the energization test, the energization test and selection test after the cutting were not necessary. A plurality of I-V data was measured at once. Thus, the steps are simplified, the production efficiency was improved and the production cost is reduced.

### Example 2

Three 70-μm sheets obtained by impregnating glass fibers with a thermosetting silicone resin composition containing alumina (available from Admatechs Company Limited., trade name: AO-502) as a metal oxide were stacked. A 75-μm copper layer was formed on the upper and lower surfaces of the layered sheets, and the surface of the copper layer was plated with Ni/Pd/Au to form a metal-coating layer. The metal-coating layer was etched to form lead electrodes, and thus a base portion was produced.

A support was molded with a thermosetting silicone resin composition containing titanium oxide as a high-reflective substance by a transfer molding apparatus.

Subsequently, a concentrating solar cell module was manufactured in the same manner as in Example 1.

### Comparative Example

A support having a tapered shape in which the recess laterally extends gradually toward the top was molded integrally with polymethyl methacrylate (PMMA) on a FR-4 (flame retardant type 4) substrate to produce a base portion. On the flat bottom of recesses of the base portion, solar cells were fixed through solder with light-receiving portions faced upward. At this time, gallium arsenide solar cells were used.

Polystyrene was then poured into the recesses to encapsulate the solar cells. The encapsulated surfaces were each processed to form condensing lenses. The resultant was cut by dicing into individual concentrating solar cell modules.

The current-voltage characteristics of each of the concentrating solar cell modules produced in Examples 1 and 2 and Comparative Example were measured under irradiation of 1 kW/m² with a solar simulator (manufactured by Asahi Spectra Co., Ltd., HAL-320). The photoelectric conversion efficiency was evaluated.

The results are given in Table 1. Table 1 shows that the concentrating solar cell modules in Examples 1 and 2 are more excellent in photoelectric conversion efficiency than one in Comparative Example.

TABLE 1

| | Example | Example | Comparative |
|---|---|---|---|
| | 1 | 2 | Example |
| Photoelectric conversion | 43 | 42 | 28 |
| efficiency (%) | | | |

The substrate thermal resistance values Rj-Hs from a junction to a heat sink of the concentrating solar cell modules produced in Examples 1 and 2 and Comparative Example were measured with a transient heat measuring apparatus (manufactured by Mentor Graphics, T3star), and compared.

The results are given in Table 2. Table 2 shows that the concentrating solar cell modules in Examples 1 and 2 have improved heat dissipation properties as compared with Comparative Example.

TABLE 2

| | Example | Example | Comparative |
|---|---|---|---|
| | 1 | 2 | Example |
| Thermal resistance | 25 | 30 | 50 |
| value (° C./W) | | | |

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. A concentrating solar cell module comprising: a base portion having a plurality of mounting regions for mounting solar cells and a plurality of lead electrodes for electrically connecting the solar cells with external electrodes; a support molded with a thermosetting resin so as to surround each of the mounting regions of the base portion; the solar cells mounted on the mounting regions; and a condensing lens molded above the mounting regions so as to encapsulate the solar cells, wherein a surface of each of the mounting regions of the base portion is plated and the condensing lens is molded with a transparent thermosetting silicone resin.

2. The concentrating solar cell module according to claim 1, wherein the support is molded with a thermosetting resin containing a silicone resin having a reflectance of 90% or more with respect to a light with a wavelength ranging from 350 nm to 900 nm.

3. The concentrating solar cell module according to claim 1, wherein an inner wall surface of the support is coated with metal by vapor deposition or plating.

4. The concentrating solar cell module according to claim 2, wherein an inner wall surface of the support is coated with metal by vapor deposition or plating.

5. The concentrating solar cell module according to claim 1, wherein the mounted solar cells are connected to the respective plated mounting regions through metal or a conductive thermosetting silicone resin.

6. The concentrating solar cell module according to claim 4, wherein the mounted solar cells are connected to the respective plated mounting regions through metal or a conductive thermosetting silicone resin.

7. The concentrating solar cell module according to claim 1, wherein the support is formed from at least one material selected from a thermosetting silicone resin, an organic modified silicone resin, and a mixed resin of an epoxy resin and a silicone resin.

8. The concentrating solar cell module according to claim 6, wherein the support is formed from at least one material selected from a thermosetting silicone resin, an organic modified silicone resin, and a mixed resin of an epoxy resin and a silicone resin.

9. The concentrating solar cell module according to claim 1, wherein the support contains at least one selected from the group consisting of a filler, a dispersing agent, a pigment, a fluorescent substance, a reflective substance, a light-shielding substance, and a fibrous inorganic material.

10. The concentrating solar cell module according to claim 8, wherein the support contains at least one selected from the group consisting of a filler, a dispersing agent, a pigment, a fluorescent substance, a reflective substance, a light-shielding substance, and a fibrous inorganic material.

11. A method for producing a concentrating solar module comprising the steps of: preparing a base portion having a plurality of mounting regions for mounting solar cells and a plurality of lead electrodes for electrically connecting the solar cells with external electrodes; molding a support with a thermosetting resin so as to surround each of the mounting regions of the base portion; mounting the solar cells on the mounting regions; plating a surface of the mounting regions of the prepared base portion after the preparing step and before the mounting step; and molding a condensing lens above the mounting regions so as to encapsulate the solar cells, wherein the condensing lens is molded with a transparent thermosetting silicone resin in the step of molding the condensing lens.

12. The method for producing a concentrating solar cell module according to claim 11, wherein an inner wall surface of the support is coated with metal by vapor deposition or plating after the step of molding the support and before the step of molding the condensing lens.

13. The method for producing a concentrating solar cell module according to claim 11, wherein the mounted solar cells are connected to the respective plated mounting regions through metal or a conductive thermosetting silicone resin in the mounting step.

14. The method for producing a concentrating solar cell module according to claim 12, wherein the mounted solar cells are connected to the respective plated mounting regions through metal or a conductive thermosetting silicone resin in the mounting step.

15. The method for producing a concentrating solar cell module according to claim 11, wherein a part of the base portion is cut to form an electric circuit after the step of molding the condensing lens.

16. The method for producing a concentrating solar cell module according to claim 14, wherein a part of the base portion is cut to form an electric circuit after the step of molding the condensing lens.

17. The method for producing a concentrating solar cell module according to claim 11, wherein the condensing lens is molded by compression molding, transfer molding, injection molding, or cast molding in the step of molding the condensing lens.

18. The method for producing a concentrating solar cell module according to claim 16, wherein the condensing lens is molded by compression molding, transfer molding, injection molding, or cast molding in the step of molding the condensing lens.

19. The method for producing a concentrating solar cell module according to claim 11, wherein the concentrating solar module is cut by dicing into individual concentrating solar modules after the step of molding the condensing lens.

20. The method for producing a concentrating solar cell module according to claim 18, wherein the concentrating solar module is cut by dicing into individual concentrating solar modules after the step of molding the condensing lens.
